(19) United States
(12) Patent Application Publication
(10) Pub. No.: US 2026/0020357 A1
(43) Pub. Date: Jan. 15, 2026

(54) PHOTOTRANSISTOR

(71) Applicant: Taiwan-Asia Semiconductor Corporation, Hsinchu City (TW)

(72) Inventors: Kun-De LIN, Hsinchu City (TW); Wen-Tsung LAI, Hsinchu City (TW); Hou-Jun WU, Hsinchu City (TW)

(21) Appl. No.: 18/980,277

(22) Filed: Dec. 13, 2024

(30) Foreign Application Priority Data
Jul. 10, 2024 (TW) 113125898

(51) Int. Cl. H10F 30/24; H10F 77/00; H10F 77/20; H10F 77/30

(52) U.S. Cl. CPC H10F 30/245; H10F 77/206; H10F 77/306; H10F 77/933

(57) ABSTRACT

A phototransistor is provided. The phototransistor includes a substrate, a light-receiving area, an emitter active area and an emitter electrode. The light-receiving area is disposed in the substrate. The emitter active area is disposed in a central area of the light-receiving area to maximize a distance between a contour edge of the emitter active area and that of the light-receiving area. The emitter electrode is electrically connected to the emitter active area.

### CROSS-REFERENCES TO RELATED APPLICATIONS

This application claims the benefit of priority to Taiwanese Patent Application No. 113125898 filed on Jul. 10, 2024, which is hereby incorporated by reference in its entirety.

### BACKGROUND OF THE INVENTION

### Field of the Invention

The present invention relates to a phototransistor sensing device, in particular, to a phototransistor sensing device capable of withstanding high voltage.

### Descriptions of the Related Art

The phototransistor is a semiconductor device that can convert optical signals into electrical signals. It is similar to the traditional bipolar junction transistor (BJT). The base can be controlled by a current signal. It can also be controlled by light signals. The phototransistor is commonly used in applications of light detection such as optocouplers, photodetectors, etc.

The basic structure of a phototransistor is similar to an ordinary bipolar junction transistor, and is usually composed of an NPN or PNP structure. When light strikes the base region of a phototransistor, photons excite electrons for creating electron-hole pairs. These electrons and holes are separated under the action of the electric field and form the base collector current (IBC). Due to the flow of electrons on the base, the electrons generated mainly flow to the emitter, and the emitter-collector current (IEC) increases accordingly. IEC is usually larger than IBC because most of the electrons generated by photons flow out through the emitter, which is also the gain effect of the phototransistor. In particular, IEC and IBC have the following relationship: IEC=β×IBC, where β is the current gain of the phototransistor, and its value is greater than 1, usually between tens and hundreds.

As shown in FIG. 1, it shows a conventional phototransistor 1 with a common NPN structure. The emitter 10 of this phototransistor 1 and the emitter pad 20 above the emitter 10 are usually arranged at the edge of the device. However, this kind of transistor structure has problems such as being unable to withstand high voltage and the light-receiving area of the base being shielded by the emitter pad, which needs to be improved urgently.

### SUMMARY OF THE INVENTION

The main objective of the present invention is to provide an innovative phototransistor sensing device, which increases the capability of withstanding high voltage thereof and reduces the base light-collecting area from being shielded by the emitter pad. Thereby, the performance of the sensing device can be enhanced.

To achieve the above objective, the present invention discloses a phototransistor which includes a substrate, a light-receiving area, an emitter active area and an emitter electrode. The light-receiving area is disposed in the substrate. The emitter active area is disposed in a central area of the light-receiving area to maximize a distance between a contour edge of the emitter active area and that of the light-receiving area. The emitter electrode is electrically connected to the emitter active area.

In one embodiment of the phototransistor of the present invention, the distance between the contour edge of the emitter active area and that of the light-receiving area is the same.

In one embodiment of the phototransistor of the present invention, the contour edge of the emitter active area is a circle.

In one embodiment of the phototransistor of the present invention, the contour edge of the emitter active area is a quadrilateral.

In one embodiment of the phototransistor of the present invention, the emitter electrode comprises a pad portion and an extension portion, the pad portion is disposed on the contour edge of the light-receiving area, and ‘the extension extends from the pad portion to the emitter active area for electrically connected to the emitter active area.

In one embodiment of the phototransistor of the present invention, the extension portion comprises a contour shape corresponding to the contour edge of the emitter active area.

In one embodiment of the phototransistor of the present invention, the contour of the extension portion is one of a closed hollow loop or an open hollow loop for substantially reducing the light-receiving area therebelow from being shielded by the emitter active area.

In one embodiment of the phototransistor of the present invention, the contour of the extension portion is a strip for substantially reducing the light-receiving area therebelow from being shielded by the emitter active area.

In one embodiment of the phototransistor of the present invention, the emitter electrode further comprises an outer loop portion, extending from the pad portion for being disposed to surround the edge of the light-receiving area therebelow.

In one embodiment of the phototransistor of the present invention, the phototransistor further comprises a base electrode, electrically connected to the light-receiving area, and disposed at a diagonal position relative to the pad portion.

In one embodiment of the phototransistor of the present invention, the phototransistor further comprises a base electrode, electrically connected to the light-receiving area, and disposed on a parallel side of the light receiving area relative to the pad portion.

In one embodiment of the phototransistor of the present invention, the substrate is a collector.

In one embodiment of the phototransistor of the present invention, the phototransistor further comprises a collector electrode, disposed on the substrate corresponding to another side of the light-receiving area.

In one embodiment of the phototransistor of the present invention, the phototransistor further comprises an anti-reflective coating, disposed on the light-receiving area and a portion of the substrate.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a top view schematic diagram of a conventional phototransistor;

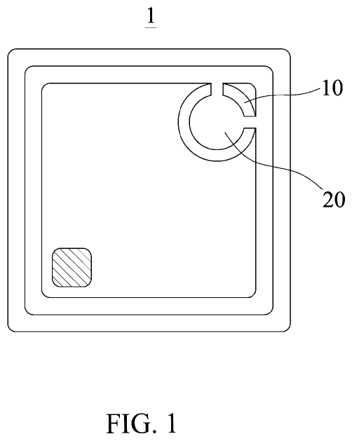

FIG. 2 is a schematic diagram of a phototransistor in an embodiment of the present invention;

FIG. 3 is a top view schematic diagram of various embodiments of the phototransistor of the present invention;

FIG. 4 is a top view schematic diagram of various embodiments of the phototransistor of the present invention;

FIG. 5 is a top view schematic diagram of various embodiments of the phototransistor of the present invention; and

FIG. 6 is a top view schematic diagram of various embodiments of the phototransistor of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

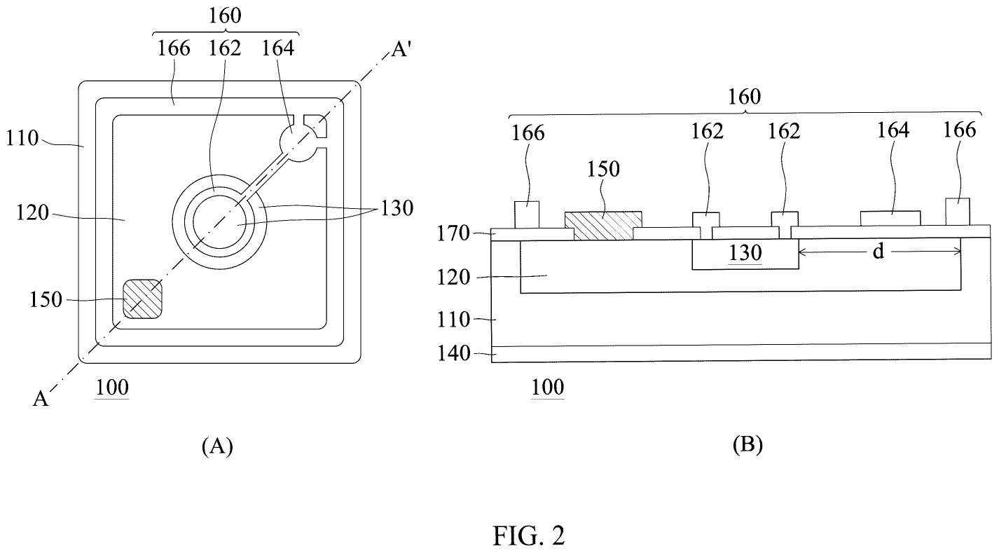

The present invention relates to a phototransistor sensing device, specifically a design for a phototransistor sensing device capable of withstanding high voltage. Please refer to FIG. 2(A) and FIG. 2(B), where FIG. 2(A) shows a top view schematic diagram of a phototransistor according to an embodiment of the present invention, and FIG. 2(B) shows a cross-sectional schematic diagram along line AA′ in FIG. 2(A). The phototransistor 100 comprises a substrate 110, a light-receiving area 120, an emitter active area 130, a collector electrode 140, a base electrode 150, and an emitter electrode 160, as shown in FIG. 2(B). In a specific embodiment, the substrate 110 may be formed using an epitaxial growth method to create an N-type compound semiconductor layer, such as an N-type gallium arsenide (GaAs) layer, which is doped with sulfur (S) or silicon (Si) as the N-type dopant at a low concentration of approximately 10¹⁵ to 10¹⁷/cm³, but is not limited thereto. The light-receiving area 120 is a P-type compound semiconductor layer disposed in the substrate 110. For example, it can be a P-type gallium arsenide (GaAs) layer, doped with zinc (Zn) or magnesium (Mg) as the P-type dopant, with a moderate doping concentration of approximately 10¹⁷ to 10¹⁹/cm³. The emitter active area 130 is an N-type compound semiconductor layer disposed in the central region of the light-receiving area 120. The emitter active area 130 can be an N-type gallium arsenide (GaAs) layer doped with sulfur (S) or silicon (Si) as the N-type dopant at a high doping concentration of approximately 10¹⁸ to 10²⁰/cm³, but is not limited thereto.

In this embodiment, the structure of the phototransistor 100 is exemplified by an NPN-type bipolar junction transistor. The substrate 110 serves as the collector of the phototransistor 100, the light-receiving area 120 serves as the base, and the emitter active area 130 serves as the emitter. When the surface of the light-receiving area 120 is exposed to light, it effectively absorbs photons for exciting electrons and generating electron-hole pairs that are separated under the influence of an electric field to form a current. The electron-hole pairs are collected between the light-receiving area 120 and the substrate 110 for forming the base-collector current (IBC). On the other hand, due to the flow of electrons in the light-receiving area 120, the emitter-collector current (IEC) between the emitter active area 130 and the substrate 110 increases accordingly. In another embodiment, the structure of the phototransistor 100 may also be a PNP-type bipolar junction transistor, which can be easily derived by those skilled in the art after understanding the present invention. Therefore, the following description will use the NPN-type bipolar junction transistor as an example to explain the technical features of the present invention in detail.

To improve the issue of poor high voltage resistance in conventional phototransistors, one of the technical features of the present invention is to adjust the emitter active area to enhance the capability of withstanding high voltage of the phototransistor sensing device. As shown in FIG. 2(B), it has been found that the distance (d) between the contour edge of the emitter active area 130 and the contour edge of the light-receiving area 120 can significantly affect the capability of withstanding high voltage of the phototransistor. Therefore, to improve the capability of withstanding high voltage, the present invention specifically maximizes the distance (d) between the contour edge of the emitter active area 130 and the contour edge of the light-receiving area 120. As shown in the figure, the phototransistor 100 of the present invention changes the traditional structure where the emitter active area is disposed at the edge of the device. Instead, the emitter active area 130 is placed in the central region of the light-receiving area 120 for thereby increasing the distance between the contour edge of the emitter active area 130 and the contour edge of the light-receiving area 120.

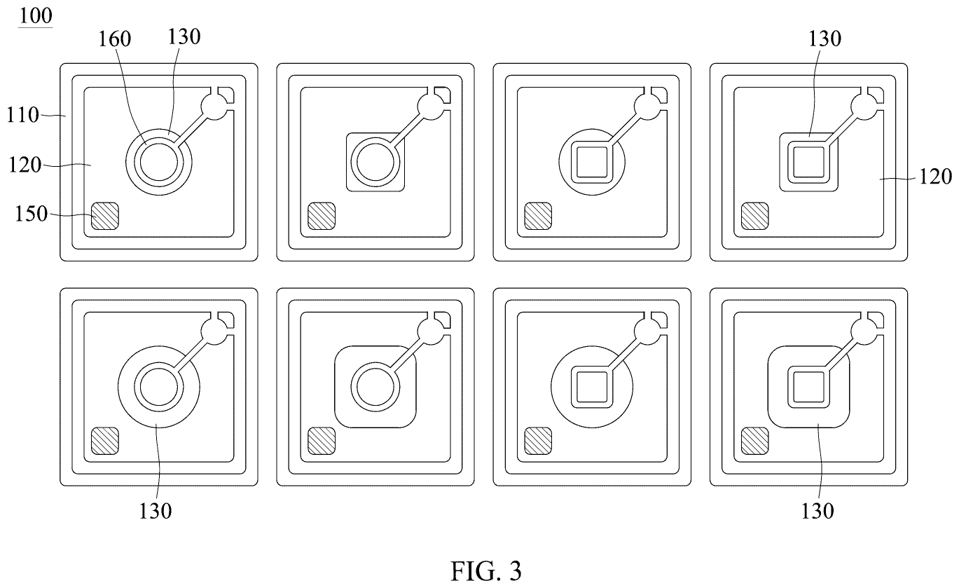

Please refer to FIG. 3, which shows a top view schematic diagram of various embodiments of the phototransistors according to the present invention. FIG. 3 illustrates different designs of the emitter active areas 130 in various embodiments of the phototransistors 100, such as different sizes and contour shapes. For example, the contour edge of the emitter active area can be circular, quadrilateral, or other arbitrary shapes. A circular emitter active area can satisfy the condition of minimizing the emitter area, while a quadrilateral emitter active area can maintain an equidistant relationship between the contour edges of the emitter active area and the light-receiving area 120 for thereby increasing the capability of withstanding high voltage of the device. Furthermore, the size of the emitter active area can also be adjusted according to the requirements of the characteristics of the sensing device.

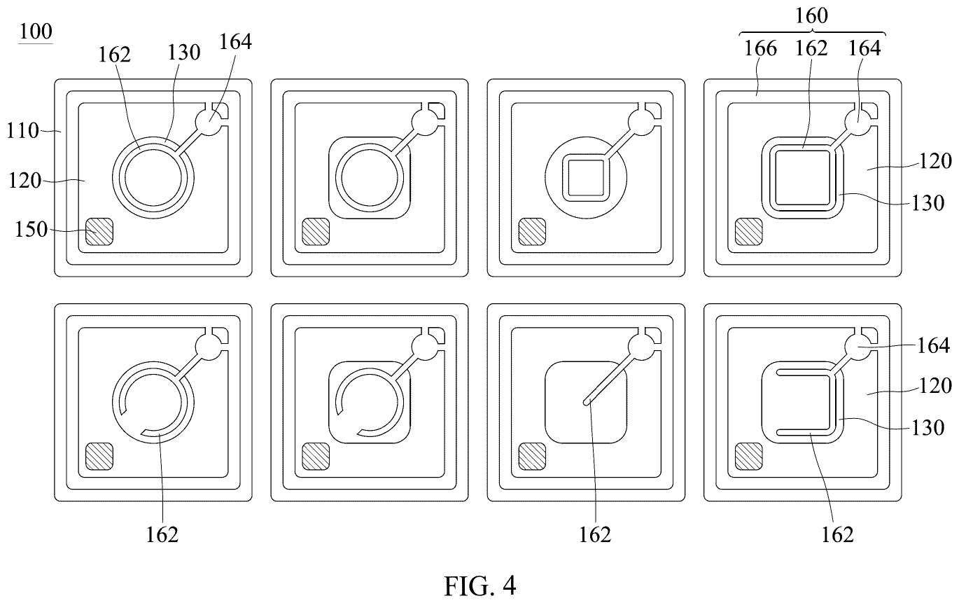

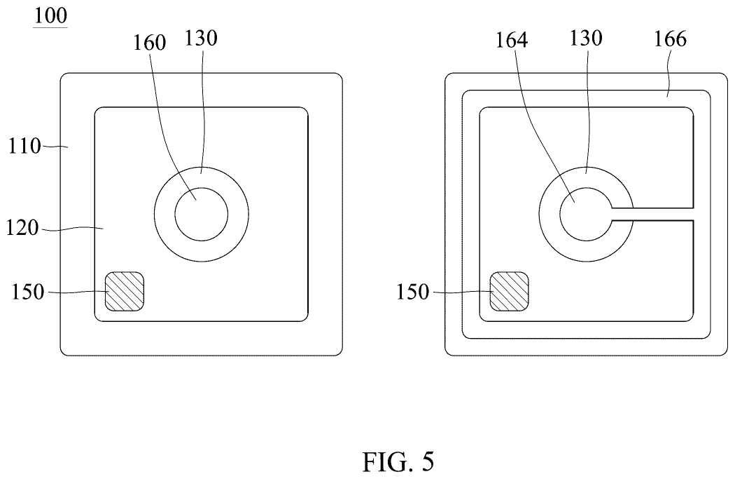

As shown in FIG. 2(B), the collector electrode 140 of the phototransistor 100 is disposed on the side of the substrate 110 opposite to the light-receiving area 120 and is electrically connected to the substrate 110. Additionally, the emitter electrode 160 includes an extension portion 162, a pad portion 164, and an outer loop portion 166. The pad portion 164 is disposed above the contour edge of the light-receiving area 120, and the extension portion 162 extends from the pad portion 164 to the emitter active area 130 to electrically connect to the emitter active area 130. Since the electrodes of the phototransistor are made of opaque metal materials, to avoid the extension portion 162 above the emitter active area 130 from excessively shielding the light-receiving area 120 below the emitter active area 130, the present invention designs the extension portion 162 extending from the pad portion 164 above the emitter active area 130 as a hollow loop or strip. As shown in FIG. 4, the extension portion 162 can be either a closed hollow loop or an open hollow loop, and can also be designed as a strip. Thereby, the hollow loop substantially reduces the light-receiving area therebelow from being shielded by the emitter active area for achieving optimal current path design. Moreover, as shown in FIG. 3 and FIG. 4, the extension portion 162 can be designed according to the contour edge of the emitter active area 130, such as a circular, quadrilateral closed hollow loop, open hollow loop, or strip. Furthermore, since the extension portion 162 of the emitter electrode 160 is designed as a hollow loop or strip, the pad portion 164 used for external wire bonding is arranged as far as possible above the contour edge of the light-receiving area 120, as shown in the figure, disposed at the corner of the device edge to substantially reduce the shielding effect of the opaque pad on the light-receiving area. Similarly, the outer loop portion 166 of the emitter electrode 160 extends outwardly from the pad portion 164 to surround the contour edge of the light-receiving area 120. However, the present invention can also adapt to different specification requirements of phototransistor sensing devices in practical applications by designing the emitter electrode 160 without any extension portion or outer loop portion, or by placing the pad portion 164 above the emitter active area 130, as shown in FIG. 5, which are also possible embodiments of the present invention.

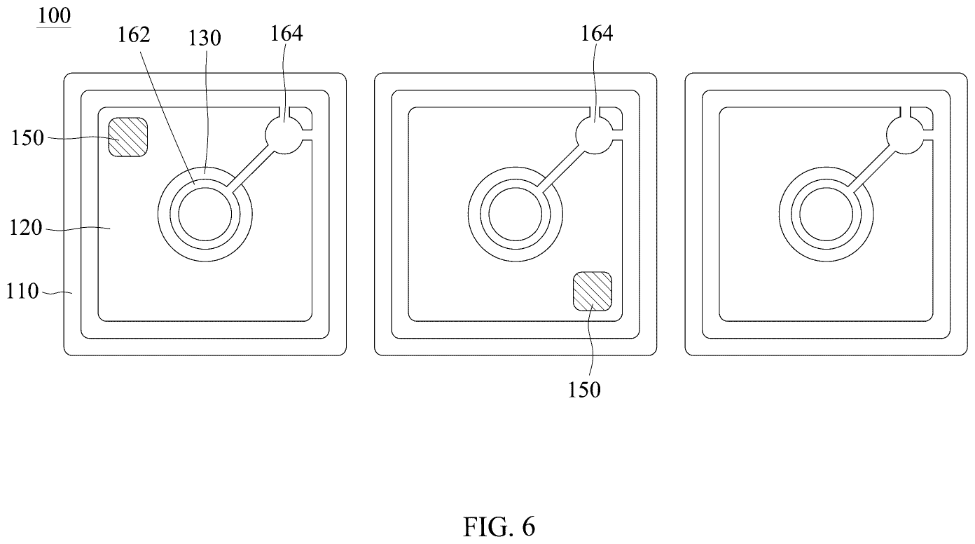

Please refer to FIG. 2(A) and FIG. 6, which show various designs of the base electrode 150 in different embodiments of the phototransistor 100 according to the present invention. The base electrode 150 of the phototransistor 100 is disposed above the light-receiving area 120 and is electrically connected to the light-receiving area 120. When the phototransistor 100 is not exposed to external light, an external IBC current can be provided through the base electrode 150 to induce an IEC current. As shown in FIG. 2(A), the base electrode 150 of the phototransistor 100 can be disposed at a diagonal position relative to the pad portion 164, or on a parallel side relative to the pad portion 164, as shown in FIG. 6. Moreover, FIG. 6 also illustrates that in specific designs of certain phototransistor sensing devices, the configuration of the base electrode 150 can be omitted, and relying solely on external light to form an IBC current is also a possible embodiment of the present invention.

In the preferable embodiment, the surface of the phototransistor 100 is equipped with an anti-reflective coating to improve photoelectric conversion efficiency. As shown in FIG. 2(B), the anti-reflective coating 170 is disposed above the light-receiving area 120 and a portion of the substrate 110 to reduce reflection losses of external light on the surface of the phototransistor and increase the transmittance of incident light. This allows more external light to enter the phototransistor and be absorbed by the light-receiving area 120 for generating more electron-hole pairs and thereby enhancing photoelectric conversion efficiency. The material for the anti-reflective coating 170 can be selected from silicon dioxide (SiO₂), silicon nitride (Si₃N₄), aluminum oxide (Al₂O₃), magnesium fluoride (MgF₂), or the like.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A phototransistor, comprising:
a substrate;
a light-receiving area, disposed in the substrate;
an emitter active area, disposed in a central area of the light-receiving area to maximize a distance between a contour edge of the emitter active area and that of the light-receiving area; and
an emitter electrode, electrically connected to the emitter active area.

2. The phototransistor of claim 1, wherein the distance between the contour edge of the emitter active area and that of the light-receiving area is the same.

3. The phototransistor of claim 1, wherein the contour edge of the emitter active area is a circle.

4. The phototransistor of claim 1, wherein the contour edge of the emitter active area is a quadrilateral.

5. The phototransistor of claim 1, wherein the emitter electrode comprises a pad portion and an extension portion, the pad portion is disposed on the contour edge of the light-receiving area, and ‘the extension extends from the pad portion to the emitter active area for electrically connected to the emitter active area.

6. The phototransistor of claim 5, wherein the extension portion comprises a contour shape corresponding to the contour edge of the emitter active area.

7. The phototransistor of claim 5, wherein the contour of the extension portion is one of a closed hollow loop or an open hollow loop for substantially reducing the light-receiving area therebelow from being shielded by the emitter active area.

8. The phototransistor of claim 5, wherein the contour of the extension portion is a strip for substantially reducing the light-receiving area therebelow from being shielded by the emitter active area.

9. The phototransistor of claim 5, wherein the emitter electrode further comprises an outer loop portion, extending from the pad portion for being disposed to surround the edge of the light-receiving area therebelow.

10. The phototransistor of claim 5, further comprising a base electrode, electrically connected to the light-receiving area, and being disposed at a diagonal position relative to the pad portion.

11. The phototransistor of claim 5, further comprising a base electrode, electrically connected to the light-receiving area, and disposed on a parallel side of the light receiving area relative to the pad portion.

12. The phototransistor of claim 1, wherein the substrate is a collector.

13. The phototransistor of claim 12, further comprising a collector electrode, disposed on the substrate corresponding to another side of the light-receiving area.

14. The phototransistor of claim 12, further comprising an anti-reflective coating, disposed on the light-receiving area and a portion of the substrate.
